(19) United States
(12) Patent Application Publication
(10) Pub. No.: US 2026/0314134 A1
(43) Pub. Date: Oct. 8, 2026

(54) LIGHT EMITTING DEVICE

(71) Applicant: NICHIA CORPORATION, Anan-shi (JP)

(72) Inventors: Kosuke SATO, Anan-shi (JP); Hiroki TOMINAGA, Tokushima-shi (JP)

(73) Assignee: NICHIA CORPORATION, Anan-shi (JP)

(21) Appl. No.: 19/529,642

(22) Filed: Feb. 4, 2026

(30) Foreign Application Priority Data
Apr. 7, 2025 (JP) 2025-062942

(51) Int. Cl. H10H 20/857; H10H 20/831; H10H 20/85; H10H 20/855

(52) U.S. Cl. CPC H10H 20/857; H10H 20/831; H10H 20/8508; H10H 20/855

(57) ABSTRACT

A light-emitting device includes a substrate including terminal parts, a light-emitting element including electrode parts, and bonding parts that bond the substrate and the light-emitting element. The terminal parts include a central terminal part having a surface in which a first recessed portion is disposed, and peripheral terminal parts each having a surface in which a second recessed portion is disposed. The electrode parts include a central electrode part having a surface in which a third recessed portion is disposed, and peripheral electrode parts each having a surface in which a fourth recessed portion is disposed. A center-to-center distance between the second recessed portions of adjacent peripheral terminal parts differs from a center-to-center distance between the fourth recessed portions of corresponding adjacent ones of the peripheral electrode parts. The center of at least one of the fourth recessed portions does not overlap a corresponding one of the second recesses portions.

### CROSS-REFERENCE TO RELATED APPLICATION

This application claims priority to Japanese Patent Application No. 2025-062942, filed on Apr. 7, 2025, the disclosure of which is hereby incorporated by reference in its entirety.

### TECHNICAL FIELD

An embodiment relates to a light-emitting device.

### BACKGROUND

A light-emitting device including a plurality of light-emitting elements has been proposed (for example, Japanese Patent Publication No. 2019-096783). To further increase the number of pixels of such a light-emitting device, a technique for achieving a plurality of pixels in one chip has been proposed. However, if obtaining a plurality of pixels in one chip is achieved, there is a possibility that the bonding strength between the substrate and the chip may decrease.

### SUMMARY

An object of the embodiment is to provide a light-emitting device capable of improving bonding strength between a substrate and a chip in the light-emitting device in which a plurality of pixels can be obtained in one chip.

A light-emitting device according to one embodiment includes a substrate having an upper surface and including a plurality of terminal parts disposed on an upper surface side, a light-emitting element having a lower surface and including a plurality of electrode parts disposed on a lower surface side, the electrode parts being arranged on the terminal parts, and a plurality of bonding parts bonding the substrate and the light-emitting element. The terminal parts include a central terminal part including a first recessed portion on a surface, and a plurality of peripheral terminal parts at least partially surrounding the central terminal part, each including a second recessed portion on a surface. The electrode parts include a central electrode part connected to the central terminal part and having a third recessed portion on a surface, and a plurality of peripheral electrode parts that each include a fourth recessed portion on a surface, at least partially surrounds the central electrode part, and are each connected to a corresponding one of the peripheral terminal parts. The bonding parts include a central bonding part that is partially disposed in the first recessed portion and the third recessed portion, and bonds the central electrode part and the central terminal part, and a plurality of peripheral bonding parts that are partially disposed in a corresponding one of the second recessed portions of the peripheral terminal parts and in a corresponding one of the fourth recessed portions of the peripheral electrode parts, and each bond a corresponding one of the peripheral electrode parts and the corresponding one of the peripheral terminal parts. A center-to-center distance between the second recessed portions of adjacent ones of the peripheral terminal parts differs from a center-to-center distance between the fourth recessed portions of the corresponding adjacent ones of the peripheral electrode parts. In a plan view, the center of at least one of the fourth recessed portions does not overlap the corresponding one of the second recessed portions.

According to certain embodiments, it is possible to achieve a light-emitting device capable of improving bonding strength between a substrate and a chip in the light-emitting device in which a plurality of pixels can be obtained in one chip.

### BRIEF DESCRIPTION OF DRAWINGS

FIG. 1 is a plan view showing the light-emitting device according to the embodiment.

FIG. 2 is a plan view showing region II of FIG. 1.

FIG. 3A is a cross-sectional view taken along line IIIA-IIIA in FIG. 2.

FIG. 3B is a cross-sectional view taken along line IIIB-IIIB in FIG. 2.

FIG. 4 is a plan view showing the substrate of the light-emitting device according to the embodiment.

FIG. 5 is a bottom view showing the light-emitting element of the light-emitting device according to the embodiment.

FIG. 6 is a plan view showing a manufacturing method of the light-emitting device according to the embodiment.

FIG. 7 is a plan view showing a manufacturing method of the light-emitting device according to the embodiment.

FIG. 8A is a cross-sectional view taken along line VIIIA-VIIIA in FIG. 7.

FIG. 8B is a cross-sectional view taken along line VIIIB-VIIIB in FIG. 7.

FIG. 9 is a cross-sectional view showing a light-emitting device according to a modification.

### DETAILED DESCRIPTION

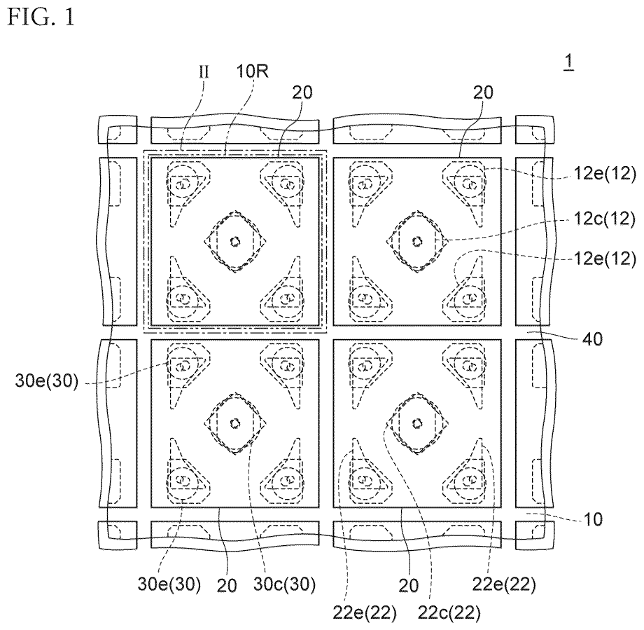

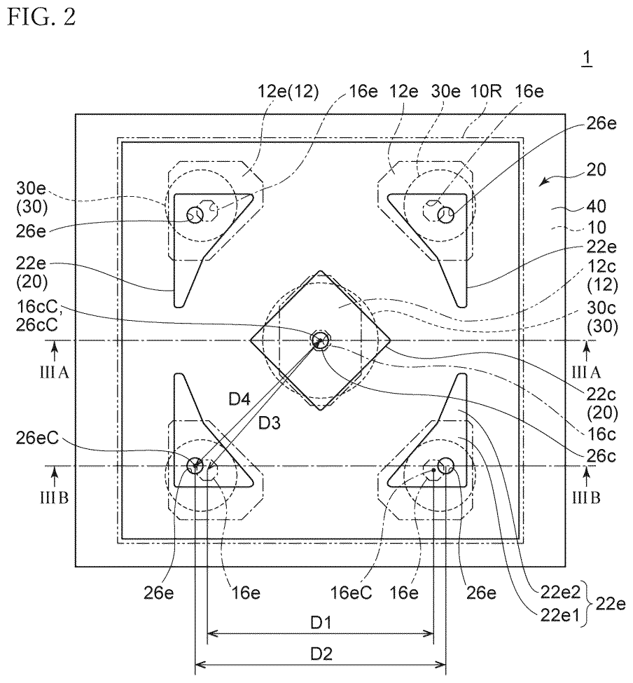

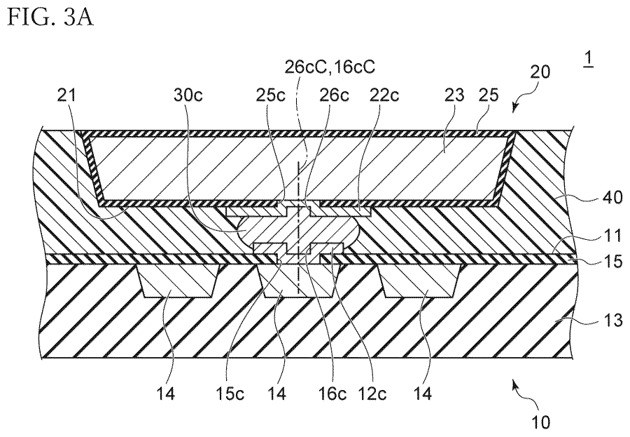

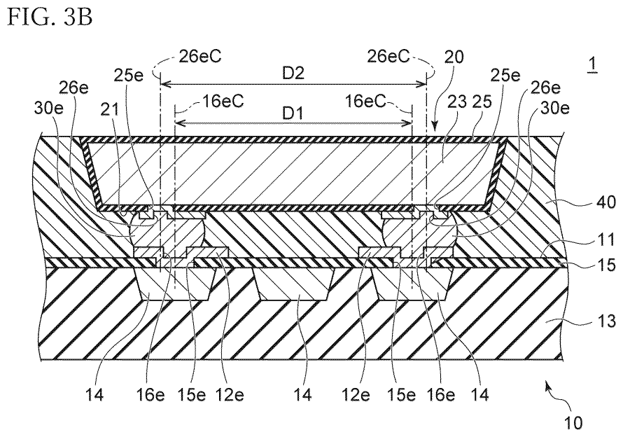

FIG. 1 is a plan view showing the light-emitting device according to an embodiment. FIG. 2 is a plan view showing region II of FIG. 1. FIG. 3A is a cross-sectional view taken along line IIIA-IIIA in FIG. 2. FIG. 3B is a cross-sectional view taken along line IIIB-IIIB in FIG. 2. In FIG. 2, for convenience of illustration, the terminal parts 12 to be described later are indicated by chain-dotted lines, the bonding parts 30 are indicated by dashed lines, and the electrode parts 22 are indicated by solid lines.

As shown in FIGS. 1 to 3B, the light-emitting device 1 according to the embodiment includes a substrate 10, a light-emitting element 20, and a plurality of bonding parts 30. The light-emitting device 1 may further include a light-shielding member 40 that covers lateral surfaces of the light-emitting element 20.

Hereinafter, a direction from the substrate 10 toward the light-emitting element 20 is referred to as “up” and the opposite direction as “down,” but these expressions are for convenience and are unrelated to the direction of gravity. In this specification, “in a plan view” means viewed in an upwards or downwards direction. In a plan view, components that are actually hidden by other components may be described as if they were visible.

The term “on” in the present disclosure encompasses both a configuration in which a member is disposed directly on and in contact with another member and a configuration in which a member is disposed on another member with a space or an intervening member interposed therebetween. Also, the term “cover” in the present disclosure encompasses both a configuration in which a member directly covers and in contact with another member and a configuration in which a member covers another member with a space or an intervening member interposed therebetween.

In the light-emitting device 1, a plurality of light-emitting elements 20 are arranged on the substrate 10 in a matrix shape separated from one another. On the substrate 10, unit regions 10R corresponding to the respective light-emitting elements 20 are arranged in a matrix shape. Hereinafter, a description will mainly be given of one unit region 10R in which one light-emitting element 20 is arranged on the substrate 10, but the same applies to the other light-emitting elements 20 and unit regions 10R. In a plan view, shapes of the light-emitting element 20 and the unit region 10R are, for example, square.

### Substrate 10

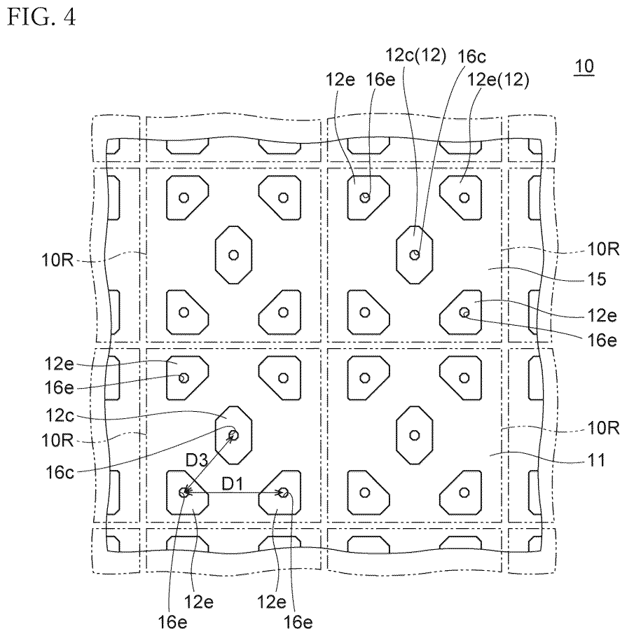

FIG. 4 is a plan view showing the substrate of the light-emitting device according to the embodiment. As shown in FIGS. 3A, 3B and 4, the substrate 10 has an upper surface 11, and includes a plurality of terminal parts 12 disposed on the upper surface 11 side. The upper surface 11 of the substrate 10 is a surface facing the light-emitting element 20. The substrate 10 may further include an insulating base member 13, wiring 14 disposed in the base member 13, and an insulating film 15 disposed on the base member 13. The base member 13 includes, for example, silicon (Si). The wiring 14 includes, for example, copper (Cu). The insulating film 15 includes, for example, silicon nitride (SiN). The substrate 10 is, for example, an ASIC (Application Specific Integrated Circuit) substrate.

The insulating film 15 has a first opening portion 15c and a plurality of second opening portions 15e. The first opening portion 15c is arranged at one location in a central portion of the unit region 10R. The second opening portions 15e are respectively arranged at the four corner portions of the unit region 10R. In a plan view, shapes of the first opening portion 15c and the second opening portions 15e are, for example, circular or substantially circular.

The plurality of terminal parts 12 include a central terminal part 12c and a plurality of peripheral terminal parts 12e. The plurality of peripheral terminal parts 12e are arranged to surround the central terminal part 12c. For example, the central terminal part 12c is arranged at a central portion of the unit region 10R, and the peripheral terminal parts 12e are respectively arranged at the four corner portions of the unit region 10R. Therefore, the number of peripheral terminal parts 12e arranged in each unit region 10R is four. The central terminal part 12c is arranged inside a virtual rectangular region connecting the four peripheral terminal parts 12e. For example, in a plan view, the arrangement of the four peripheral terminal parts 12e is four-fold symmetric with respect to the center of the central terminal part 12c. The number of peripheral terminal parts 12e is not limited to four and may be two or more.

In a plan view, the shape of the central terminal part 12c is, for example, a substantially octagonal shape that the four corner portions of a rectangle are absent. A part of the central terminal part 12c is positioned in the first opening portion 15c of the insulating film 15 and is connected to a part of the wiring 14. An upper surface of the portion of the central terminal part 12c positioned in the first opening portion 15c conforms to the shape of the first opening portion 15c to form a first recessed portion 16c. Therefore, the central terminal part 12c has the first recessed portion 16c on the surface. In a plan view, the shape of the first recessed portion 16c is, for example, circular or substantially circular. The remaining portion of the central terminal part 12c is arranged on the insulating film 15. The shape of the central terminal part 12c is not limited to the above example.

In a plan view, the shape of each peripheral terminal part 12e is, for example, a substantially pentagonal shape that one corner portion of a rectangle facing the central terminal part 12c is absent. A part of each peripheral terminal part 12e is arranged in each second opening portion 15e of the insulating film 15 and is connected to another part of the wiring 14. An upper surface of the portion of each peripheral terminal part 12e arranged in the second opening portion 15e conforms to the shape of the second opening portion 15e to form a second recessed portion 16e. Therefore, each of the plurality of peripheral terminal parts 12e has the second recessed portion 16e on the surface. In a plan view, the shape of the second recessed portion 16e is, for example, circular or substantially circular. The remaining portion of each peripheral terminal part 12e is positioned on the insulating film 15. The shape of the peripheral terminal part 12e is not limited to the above example.

### Light-emitting Element 20

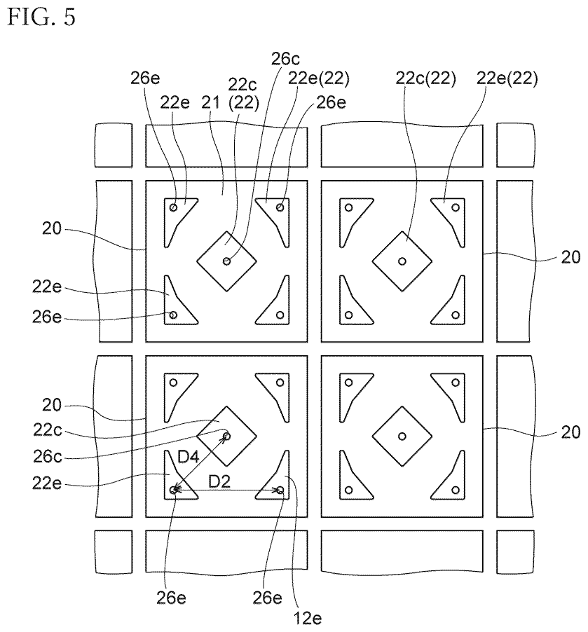

FIG. 5 is a bottom view showing the light-emitting element of the light-emitting device according to the embodiment. As shown in FIGS. 3A, 3B and 5, the light-emitting element 20 has a lower surface 21 and a plurality of electrode parts 22 disposed on the lower surface 21 side. The lower surface 21 of the light-emitting element 20 is a surface facing the substrate 10. The light-emitting element 20 may further include a semiconductor layered body 23 and an insulating film 25 covering the semiconductor layered body 23. In the semiconductor layered body 23, a p-type semiconductor layer, an active layer, and an n-type semiconductor layer are layered. The insulating film 25 includes, for example, silicon nitride.

The insulating film 25 has a third opening portion 25c and a plurality of fourth opening portions 25e on the lower surface 21 side. The third opening portion 25c is arranged at one location in a central portion of the lower surface 21. The fourth opening portions 25e are respectively arranged at the four corner portions of the lower surface 21. In a plan view, the shapes of the third opening portion 25c and the fourth opening portions 25e are, for example, circular or substantially circular.

The plurality of electrode parts 22 include a central electrode part 22c and a plurality of peripheral electrode parts 22e. The plurality of peripheral electrode parts 22e are arranged to surround the central electrode part 22c. For example, the central electrode part 22c is arranged at a central portion of the lower surface 21 of the light-emitting element 20, and the peripheral electrode parts 22e are respectively arranged at the four corner portions of the lower surface 21. In this case, the number of peripheral electrode parts 22e is four. The number of peripheral electrode parts 22e is not limited to four and may be two or more. It is preferable that the number of peripheral electrode parts 22e is equal to the number of peripheral terminal parts 12e provided in each unit region 10R of the substrate 10.

In a plan view, an outer edge of the central electrode part 22c is a quadrilateral having point symmetry and is, for example, a rhombus or a square. On the other hand, in a plan view, an outer edge of each peripheral electrode part 22e is a substantially right triangle, with a hypotenuse being a concave curve. The concave curve of the outer edge of each peripheral electrode part 22e faces corresponding one of the sides of the outer edge of the central electrode part 22c. The arrangement of the four peripheral electrode parts 22e is a mirror image with respect to two straight lines that are parallel to an outer edge of the lower surface 21 of the light-emitting element 20 and pass through the center of the lower surface 21.

A part of the central electrode part 22c is arranged in the third opening portion 25c of the insulating film 25 and is connected to a part of the semiconductor layered body 23, for example, to the n-type semiconductor layer. In this case, the central electrode part 22c is a cathode electrode of the light-emitting element 20. A lower surface of the portion of the central electrode part 22c positioned in the third opening portion 25c conforms to the shape of the third opening portion 25c to form a third recessed portion 26c. Therefore, the central electrode part 22c has the third recessed portion 26c on the surface. In a plan view, the shape of the third recessed portion 26c is, for example, circular or substantially circular. The remaining portion of the central electrode part 22c is arranged on the lower surface of the insulating film 25. The shape of the central electrode part 22c is not limited to the above example.

A part of each peripheral electrode part 22e is positioned in corresponding one of the fourth opening portions 25e of the insulating film 25, and is connected to another part of the semiconductor layered body 23, for example, to the p-type semiconductor layer. In this case, each peripheral electrode part 22e is an anode electrode of the light-emitting element 20. A lower surface of the portion of each peripheral electrode part 22e positioned in the fourth opening portion 25e conforms to the shape of the fourth opening portion 25e to form a fourth recessed portion 26e. Therefore, each of the plurality of peripheral electrode parts 22e has the fourth recessed portion 26e on the surface. In a plan view, the shape of the fourth recessed portion 26e is, for example, circular or substantially circular. The remaining portion of each peripheral electrode part 22e is positioned on the lower surface of the insulating film 25. The shape of the peripheral electrode part 22e is not limited to the above example.

As described above, in the example shown in the embodiment, in the light-emitting element 20, one central electrode part 22c is arranged at a central portion of the lower surface 21, and is connected to the n-type semiconductor layer of the semiconductor layered body 23. The central electrode part 22c is a common cathode electrode of the light-emitting element 20. The four peripheral electrode parts 22e are respectively arranged at the four corner portions of the lower surface 21 so as to form substantially four-fold symmetry, and are connected to the p-type semiconductor layer of the semiconductor layered body 23. The four peripheral electrode parts 22e are anode electrodes independent from each other. In the semiconductor layered body 23, the p-type semiconductor layer and the active layer are divided for each peripheral electrode part 22e. Accordingly, in the light-emitting element 20, the four divided portions can be independently driven, and four pixels can be obtained in one light-emitting element 20.

### Bonding Part 30

As shown in FIGS. 1, 2, 3A, and 3B, the plurality of bonding parts 30 bond the substrate 10 and the light-emitting element 20. In this specification, “bonding” means being electrically connected and mechanically joined. The plurality of bonding parts 30 include a central bonding part 30c and a plurality of peripheral bonding parts 30e.

The central bonding part 30c is in contact with the central terminal part 12c of the substrate 10 and the central electrode part 22c of the light-emitting element 20, and bonds the central terminal part 12c and the central electrode part 22c. Accordingly, the central electrode part 22c is connected to the central terminal part 12c. A part of the central bonding part 30c is disposed in the first recessed portion 16c of the central terminal part 12c of the substrate 10, and another part of the central bonding part 30c is disposed in the third recessed portion 26c of the central electrode part 22c of the light-emitting element 20.

Each peripheral bonding part 30e is in contact with a corresponding peripheral terminal part 12e of the substrate 10 and a corresponding peripheral electrode part 22e of the light-emitting element 20, and bonds each peripheral electrode part 22e and the corresponding one of the peripheral terminal parts 12e. Accordingly, each peripheral electrode part 22e is connected to the corresponding peripheral terminal part 12e. A part of each peripheral bonding part 30e is disposed in the second recessed portion 16e of each peripheral terminal part 12e, and another part of each peripheral bonding part 30e is disposed in the fourth recessed portion 26e of the corresponding peripheral electrode part 22e.

It is preferable that the composition of the outermost surface forming the first recessed portion 16c of the central terminal part 12c of the substrate 10, the composition of the outermost surface forming the second recessed portion 16e of the peripheral terminal part 12e, the composition of the central bonding part 30c, and the composition of the peripheral bonding part 30e are identical. This can reduce thermal stress caused by differences in coefficients of thermal expansion at the interface between the central terminal part 12c and the central bonding part 30c, and at the interface between the peripheral terminal part 12e and the peripheral bonding part 30e, thereby improving reliability. These compositions are preferably gold (Au). This can improve chemical stability against corrosion and oxidation while reducing the occurrence of thermal stress.

### Light-shielding Member 40

The light-shielding member 40 is formed of an insulating and light-shielding material. The light-shielding member 40 is, for example, composed of a filler dispersed in a resin-based matrix. The matrix is, for example, silicone resin, and the filler is, for example, titanium oxide. Thus, the light-shielding member 40 is, for example, white overall. The filler may also be, for example, carbon powder such as carbon black. Thus, the light-shielding member 40 is, for example, black overall. The light-shielding member 40 is disposed between adjacent light-emitting elements 20 and in portions between the substrate 10 and the light-emitting element 20 excluding portions in which the bonding parts 30 presents, and it is in contact with the upper surface 11 of the substrate 10, the lower surface 21 and lateral surface(s) of the light-emitting element 20, and lateral surface(s) of the bonding parts 30.

Positional Relationship between Terminal Parts 12 and Electrode Parts 22

The plurality of electrode parts 22 of the light-emitting element 20 are arranged on the plurality of terminal parts 12 of the substrate 10. In a plan view, at least one center 26eC of the fourth recessed portion 26e does not overlap the corresponding second recessed portion 16e. At least one center 16eC of the second recessed portion 16e does not have to overlap the corresponding fourth recessed portion 26e. On the other hand, in a plan view, the center 26cC of the third recessed portion 26c may overlap the first recessed portion 16c, and the center 16cC of the first recessed portion 16c may overlap the third recessed portion 26c.

It is preferable that, in a plan view, each peripheral electrode part 22e has a first region 22e1 overlapping a corresponding peripheral terminal part 12e and a second region 22e2 not overlapping the corresponding peripheral terminal part 12e.

A center-to-center distance D1 between the centers of the second recessed portions 16e of adjacent peripheral terminal parts 12e differs from a center-to-center distance D2 between the centers of the fourth recessed portions 26e of the corresponding adjacent peripheral electrode parts 22e. For example, the center-to-center distance D1 is shorter than the center-to-center distance D2. In one example, in a plan view, a length of one side of the light-emitting element 20 is 45 μm, the center-to-center distance D1 is 27 μm, and the center-to-center distance D2 is 31 μm. The center-to-center distance D1 may be longer than the center-to-center distance D2. In this specification, “center” refers, for example, to a geometric centroid in a plan view.

A center-to-center distance D3 between the center of the first recessed portion 16c of the central terminal part 12c and the center of the second recessed portion 16e of the peripheral terminal part 12e of the substrate 10 differs from a center-to-center distance D4 between the center of the third recessed portion 26c of the central electrode part 22c and the center of the fourth recessed portion 26e of the peripheral electrode part 22e of the light-emitting element 20. For example, the center-to-center distance D3 is shorter than the center-to-center distance D4. In one example, in a plan view, a length of one side of the light-emitting element 20 is 45 μm, the center-to-center distance D3 is 21 μm, and the center-to-center distance D4 is 22 μm. The center-to-center distance D3 may be longer than the center-to-center distance D4.

### Manufacturing Method

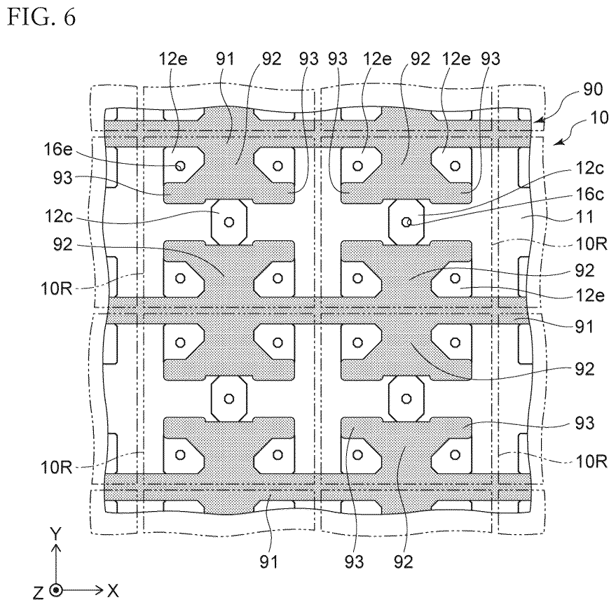

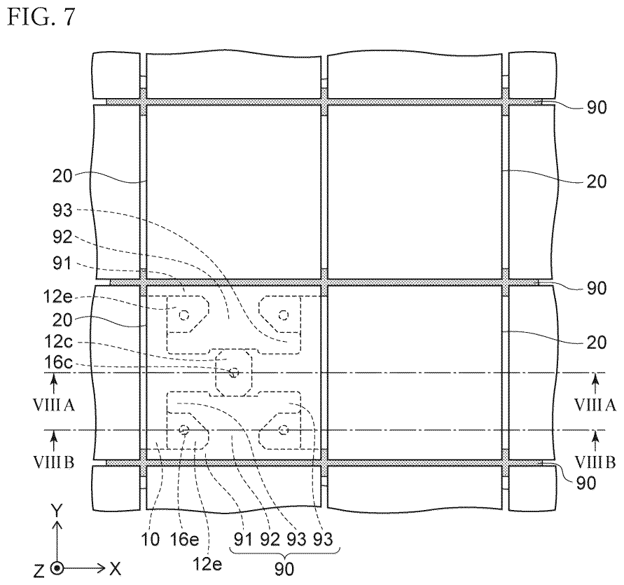

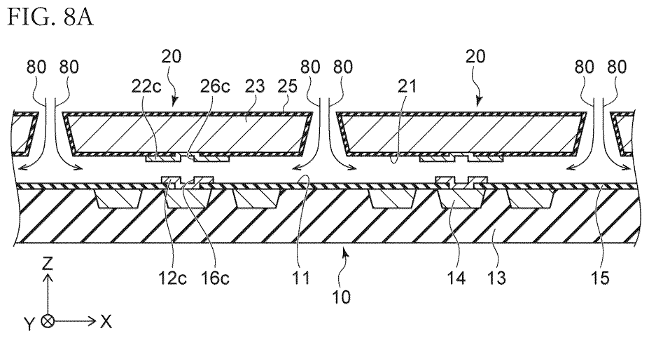

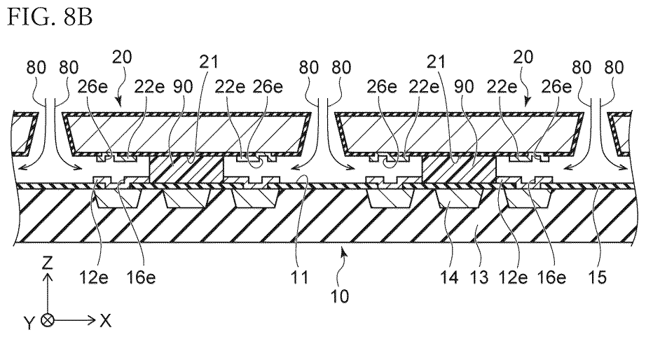

Next, a manufacturing method for the light-emitting device 1 according to the embodiment will be described. Each of FIGS. 6 and 7 is a plan view showing a manufacturing method for the light-emitting device according to the embodiment. FIG. 8A is a cross-sectional view taken along line VIIIA-VIIIA in FIG. 7. FIG. 8B is a cross-sectional view taken along line VIIIB-VIIIB in FIG. 7. In FIGS. 6 to 8B, for convenience of explanation, an XYZ orthogonal coordinate system is adopted. The X direction and the Y direction are arrangement directions of the light-emitting elements 20. The Z direction is a direction perpendicular to the upper surface 11 and is the above-mentioned upward direction.

As shown in FIG. 4, the substrate 10 is provided. The configuration of the substrate 10 is as described above. On the other hand, as shown in FIG. 5, the light-emitting element 20 is provided. For example, a plurality of light-emitting elements 20 are held on a lower surface of a transfer substrate (not shown) via an adhesive layer (not shown), arranged in a matrix shape. The configuration of each light-emitting element 20 is as described above. The order of the step of providing the substrate 10 and the step of providing the light-emitting element 20 is not particularly limited. The substrate 10 and the light-emitting element 20 may be provided by manufacturing them individually, or may be provided by receiving them from another party.

Subsequently, as shown in FIG. 6, a resist pattern 90 is formed on the upper surface 11 of the substrate 10. The resist pattern 90 is formed, for example, by applying a resist material and then performing exposure and development to pattern it. In FIG. 6, light dots are applied to the resist pattern 90 to make the figure easier to see. The resist pattern 90 includes a first portion 91, a second portion 92, and a third portion 93.

The first portion 91 extends in the X direction along a boundary of the unit region 10R. The first portion 91 is formed across a plurality of unit regions 10R arranged in the X direction. The first portion 91 is in contact with lateral surfaces of the peripheral terminal parts 12e.

The second portion 92 extends in both Y directions from the first portion 91 toward the inside of the unit region 10R. Lateral surfaces on both X-direction sides of the second portion 92 are in contact with lateral surfaces of the peripheral terminal parts 12e, and a lateral surface at the tip in the Y direction of the second portion 92 is in contact with a lateral surface of the corresponding central terminal part 12c.

The third portion 93 extends in both X directions from the lateral surfaces facing both X directions at the tip of the second portion 92. The third portion 93 is disposed between the central terminal part 12c and the peripheral terminal part 12e, separated from the central terminal part 12c, and in contact with the lateral surface of the peripheral terminal part 12e. The third portions 93 do not reach boundaries of the unit region 10R.

Accordingly, in the Y direction, the first portion 91 of the resist pattern 90 is disposed between adjacent unit regions 10R. In each unit region 10R, the second portion 92 and the third portion 93 are disposed between the central terminal part 12c and the peripheral terminal part 12e. In each unit region 10R, the second portion 92 is disposed between peripheral terminal parts 12e adjacent in the X direction. Two third portions 93 are disposed between peripheral terminal parts 12e adjacent in the Y direction.

On the other hand, on both sides of the central terminal part 12c in the X direction, spaces reaching a boundary of the unit region 10R present. In addition, on one side of the peripheral terminal part 12e in the X direction, a space reaching a boundary of the unit region 10R presents. Subsequently, as shown in FIGS. 7 to 8B, a plurality of light-emitting elements 20 are arranged on the substrate 10. The light-emitting elements 20 are placed on the resist pattern 90 by contacting the resist pattern 90. Subsequently, the transfer substrate and adhesive layer (not shown) are removed from the plurality of light-emitting elements 20.

At this stage, the positional relationship between the first recessed portion 16c of the central terminal part 12c of the substrate 10, the second recessed portion 16e of the peripheral terminal part 12e, the third recessed portion 26c of the central electrode part 22c of the light-emitting element 20, and the fourth recessed portion 26e of the peripheral electrode part 22e is as described above. In FIG. 7, for clarity, the terminal parts 12 and the resist pattern 90 are shown by dashed lines only in the area directly below one light-emitting element 20.

Subsequently, plating solution 80 is supplied from above, and plating is started. At this time, the plating solution 80 passes through gaps between the light-emitting elements 20, and enters the space between the substrate 10 and the light-emitting elements 20. For the central terminal part 12c and the central electrode part 22c, the plating solution 80 reaches from both sides in the X direction. Accordingly, metal portions grow starting from the central terminal part 12c and the central electrode part 22c. For each of the peripheral terminal parts 12e and the peripheral electrode parts 22e, the plating solution 80 reaches from one side in the X direction. Accordingly, metal portions grow starting from the peripheral terminal parts 12e and the peripheral electrode parts 22e. The metal portions may be, for example, gold films.

The metal portion grown from the central terminal part 12c and the metal portion grown from the central electrode part 22c are integrated to form the central bonding part 30c. The metal portion grown from one of the peripheral terminal parts 12e and the metal portion grown from the corresponding one of the peripheral electrode parts 22e are integrated to form the peripheral bonding part 30e. At this time, because the resist pattern 90 is interposed between the central bonding part 30c and the peripheral bonding parts 30e, and between adjacent peripheral bonding parts 30e, short-circuiting between the central bonding part 30c and the plurality of peripheral bonding parts 30e can be avoided.

In this way, a part of the wiring 14 of the substrate 10 is connected to the n-type semiconductor layer of the light-emitting element 20 via the central terminal part 12c, the central bonding part 30c, and the central electrode part 22c. Another part of the wiring 14 of the substrate 10 is connected to a part of the p-type semiconductor layer of the light-emitting element 20 via the peripheral terminal part 12e, the peripheral bonding part 30e, and the peripheral electrode part 22e. Thereafter, the resist pattern 90 is removed.

Subsequently, as shown in FIGS. 1 to 3B, a resin material containing filler is supplied through gaps between the light-emitting elements 20, and is disposed between the substrate 10 and the light-emitting elements 20, and between the light-emitting elements 20. Subsequently, the resin material is solidified. Accordingly, the light-shielding member 40 is formed. In this manner, the light-emitting device 1 is manufactured.

### Effects

In the embodiment, in the step of providing the substrate 10 and the light-emitting elements 20, the center-to-center distance D1 between the centers of the second recessed portions 16e of adjacent peripheral terminal parts 12e of the substrate 10 is made different from the center-to-center distance D2 between the centers of the fourth recessed portions 26e of the corresponding adjacent peripheral electrode parts 22e of the light-emitting element 20. Therefore, when a plurality of light-emitting elements 20 are arranged on the substrate 10, in a plan view, the center 26eC of at least one of the fourth recessed portions 26e does not overlap the corresponding second recessed portion 16e. Accordingly, when plating solution 80 is supplied, the plating solution 80 can flow more easily, making plating growth easier. Therefore, voids are less likely to form in the peripheral bonding parts 30e. Consequently, the bonding strength between the substrate 10 and the light-emitting element 20 is improved.

In contrast, if the center-to-center distance D1 is equal to the center-to-center distance D2, in every combination of the peripheral terminal part 12e and the peripheral electrode part 22e, the center 26eC of the fourth recessed portion 26e may overlap the corresponding second recessed portion 16e. In this case, the second recessed portion 16e will be positioned directly below the fourth recessed portion 26e. In such a case, a large space in the Z direction is formed, and when plating solution 80 is supplied from one side in the X direction, voids are more likely to form between the fourth recessed portion 26e and the second recessed portion 16e. If voids are formed, the strength of the peripheral bonding part 30e decreases, and the bonding strength between the substrate 10 and the light-emitting element 20 decreases.

For the central terminal part 12c and the central electrode part 22c, because plating solution 80 is supplied from both sides in the X direction, even if the first recessed portion 16c is positioned directly below the third recessed portion 26c and the center 26cC of the third recessed portion 26c overlaps the first recessed portion 16c, voids are unlikely to form, and bonding strength can be maintained.

In the embodiment, in a plan view, the outer edge of the central electrode part 22c is a quadrilateral having point symmetry, and the outer edge of each peripheral electrode part 22e is a substantially right triangle, with the hypotenuse being a concave curve. The concave curve of the outer edge of each peripheral electrode part 22e faces each side of the outer edge of the corresponding central electrode part 22c. Accordingly, the shortest distance between the central electrode part 22c and the peripheral electrode part 22e can be ensured to reduce short-circuiting, while increasing the areas of the central electrode part 22c and the peripheral electrode part 22e. Consequently, the contact area between the central electrode part 22c and the central bonding part 30c, and the contact area between the peripheral electrode part 22e and the peripheral bonding part 30e, are increased, further improving the bonding strength between the substrate 10 and the light-emitting element 20.

Furthermore, in the embodiment, in a plan view, each peripheral electrode part 22e has a first region 22e1 overlapping the corresponding peripheral terminal part 12e and a second region 22e2 not overlapping the corresponding peripheral terminal part 12e. Accordingly, during manufacturing, a margin for positional deviation is provided for the peripheral electrode part 22e, and even if positional deviation occurs when the light-emitting element 20 is arranged on the substrate 10, a large decrease in the area of the region in a plan view where the peripheral electrode part 22e overlaps the peripheral terminal part 12e can be avoided. Consequently, the width of the peripheral bonding part 30e can be ensured, and the bonding strength between the substrate 10 and the light-emitting element 20 can be maintained.

### Modification Example

Subsequently, in a modification example of the embodiment, a case will be described in which positional deviation occurs within an allowable range when a light-emitting device is manufactured by the manufacturing method described in the embodiment.

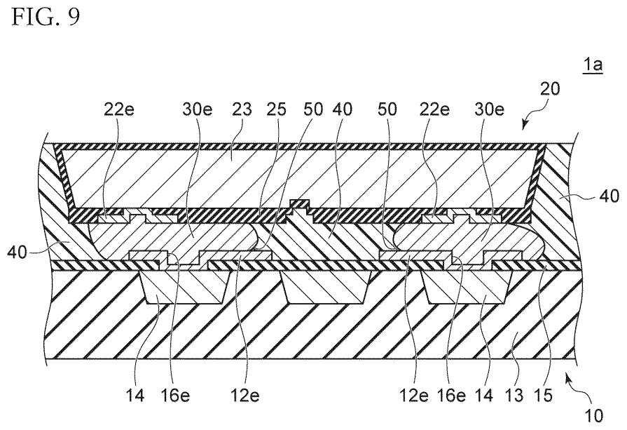

FIG. 9 is a cross-sectional view showing the light-emitting device according to the modification example. As shown in FIG. 9, in the light-emitting device 1a according to the modification example, the peripheral bonding part 30e protrudes outward relative to the peripheral terminal part 12e toward the outer periphery side of the light-emitting element 20. Accordingly, the peripheral bonding part 30e is in contact with not only the upper surface of the peripheral terminal part 12e but also with the lateral surface of a portion of the peripheral terminal part 12e positioned outside the second recessed portion 16e. In addition, the lower portion of the lateral surface of the peripheral bonding part 30e is inclined inward, and a wedge-shaped recessed portion 50 is formed between the peripheral bonding part 30e and the peripheral terminal part 12e. A part of the light-shielding member 40 is disposed inside the recessed portion 50.

In the modification example, because the peripheral bonding part 30e is in contact with the lateral surface in addition to the upper surface of the peripheral terminal part 12e, the bonding strength between the peripheral bonding part 30e and the peripheral terminal part 12e is improved by an anchor effect. Accordingly, the bonding strength between the substrate 10 and the light-emitting element 20 is improved.

In addition, because the wedge-shaped recessed portion 50 is formed between the peripheral bonding part 30e and the peripheral terminal part 12e, and a part of the light-shielding member 40 is disposed inside the recessed portion 50, the adhesion strength between the light-shielding member 40 and the structure including the peripheral bonding part 30e and the peripheral terminal part 12e is improved. Consequently, the reliability of the light-emitting device 1a is improved. Other configurations, manufacturing methods, and effects in this modification example are the same as in the embodiment.

As described above, according to the embodiment and the modification example, a light-emitting device capable of improving the bonding strength between a substrate and a chip can achieve a light-emitting device in which a plurality of pixels can be obtained in one chip.

The embodiment and the modification example described above are examples embodying the present invention, and the present invention is not limited to these embodiments and modification examples. For example, in the embodiment and each modification example described above, configurations or steps may be added, deleted, or changed, and such variations are also included in the scope of the present invention.

The present invention can be used, for example, as a light source for illumination devices and display devices, and can be used, for example, as a light source for a vehicle headlamp.

What is claimed is:

1. A light-emitting device comprising:
a substrate having an upper surface and comprising a plurality of terminal parts disposed on an upper surface side;
a light-emitting element having a lower surface and comprising a plurality of electrode parts disposed on a lower surface side, the electrode parts being arranged on the terminal parts; and
a plurality of bonding parts bonding the substrate and the light-emitting element; wherein:
the terminal parts include:
a central terminal part having a surface in which a first recessed portion is disposed; and
a plurality of peripheral terminal parts at least partially surrounding the central terminal part, each having a surface in which a second recessed portion is disposed;
the electrode parts include:
a central electrode part connected to the central terminal part and including a surface in which a third recessed portion is disposed; and
a plurality of peripheral electrode parts at least partially surrounding the central electrode part, each connected to a corresponding one of the peripheral terminal parts, and each having a surface in which a fourth recessed portion is disposed;
the bonding parts include:
a central bonding part partially disposed in the first recessed portion and the third recessed portion, and bonding the central electrode part and the central terminal part; and
a plurality of peripheral bonding parts, each partially disposed in a corresponding one of the second recessed portions of the peripheral terminal parts and in a corresponding one of the fourth recessed portions of the peripheral electrode parts, and each bonding a corresponding one of the peripheral electrode parts and the corresponding one of the peripheral terminal parts;
a center-to-center distance between the second recessed portions of adjacent ones of the peripheral terminal parts differs from a center-to-center distance between the fourth recessed portions of the corresponding adjacent ones of the peripheral electrode parts; and
in a plan view, a center of at least one of the fourth recessed portions does not overlap the corresponding one of the second recessed portions.

2. The light-emitting device according to claim 1, wherein, in the plan view, a center of the third recessed portion overlaps the first recessed portion.

3. The light-emitting device according to claim 1, wherein the center-to-center distance between the second recessed portions of the adjacent ones of the peripheral terminal parts is shorter than the center-to-center distance between the fourth recessed portions of the corresponding adjacent ones of the peripheral electrode parts.

4. The light-emitting device according to claim 1, wherein, in the plan view, an outer edge of each of the peripheral electrode parts has a concave curve facing the central electrode part.

5. The light-emitting device according to claim 4, wherein, in the plan view, an outer edge of the central electrode part is a quadrilateral having point symmetry, and each side of the outer edge of the central electrode part faces a corresponding one of the concave curves of the peripheral electrode parts.

6. The light-emitting device according to claim 1, wherein a composition of an outermost surface forming the first recessed portion of the central terminal part, a composition of an outermost surface forming the second recessed portion of the peripheral terminal part, a composition of the central bonding part, and a composition of the peripheral bonding part are identical.

7. The light-emitting device according to claim 1, wherein:
the substrate further comprises:
an insulating base member,
a wiring disposed in the base member, and
an insulating film disposed on the base member and having a first opening portion and a plurality of second opening portions;
a part of the central terminal part is disposed in the first opening portion and connected to a part of the wiring, and a remaining portion of the central terminal part is disposed on the insulating film;
a part of each peripheral terminal part is disposed in each second opening portion and connected to another part of the wiring, and a remaining portion of each peripheral terminal part is disposed on the insulating film; and
at least one of the peripheral bonding parts is in contact with a lateral surface of the remaining portion of the peripheral terminal part.

8. The light-emitting device according to claim 1, further comprising:
a light-shielding member covering a lateral surface of the light-emitting element; wherein:
a recessed portion is formed between at least one of the peripheral bonding parts and a corresponding one of the peripheral terminal parts, and a part of the light-shielding member is positioned in the recessed portion.

9. The light-emitting device according to claim 1, wherein:
in the plan view, each of the peripheral electrode parts includes:
a first region overlapping the peripheral terminal part, and
a second region not overlapping the peripheral terminal part.
